(19) United States
(12) Patent Application Publication
(10) Pub. No.: US 2016/0035657 A1
(43) Pub. Date: Feb. 4, 2016

(54) SEMICONDUCTOR DEVICE AND SEMICONDUCTOR MODULE

(71) Applicant: Kabushiki Kaisha Toshiba, Minato-ku (JP)

(72) Inventors: Taizo TOMIOKA, Yokohama (JP); Tomohiro IGUCHI, Kawasaki (JP); Takahiro AIZAWA, Yokohama (JP)

(73) Assignee: Kabushiki Kaisha Toshiba, Minato-ku (JP)

(21) Appl. No.: 14/789,365

(22) Filed: Jul. 1, 2015

(30) Foreign Application Priority Data
Aug. 4, 2014 (JP) 2014-159047

(51) Int. Cl. H01L 23/498; H01L 23/08; H01L 27/12; H01L 23/055

(52) U.S. Cl. CPC H01L 23/49811; H01L 23/49844; H01L 23/055; H01L 23/08; H01L 27/12

(57) ABSTRACT

According to one embodiment, a semiconductor device includes a first base portion, a second base portion, a third base portion, and a semiconductor element. A first end portion of the first base portion is positioned closer to a side on which the semiconductor element is provided than a second end portion of the first base portion. A third end portion of the second base portion is positioned closer to the side on which the semiconductor element is provided than a fourth end portion of the second base portion. A fifth end portion of the third base portion is positioned closer to the side on which the semiconductor element is provided than a sixth end portion of the third base portion in the third direction.

### CROSS-REFERENCE TO RELATED APPLICATIONS

This application is based upon and claims the benefit of priority from Japanese Patent Application No. 2014-159047, filed on Aug. 4, 2014; the entire contents of which are incorporated herein by reference.

### FIELD

Embodiments described herein relate generally to a semiconductor device and a semiconductor module.

### BACKGROUND

Power electronics are widely used in various technology areas such as home appliances, an automobile, a railroad, power transmission, and power generation.

A semiconductor module used in the field of power electronics includes a plurality of semiconductor devices and each semiconductor device has a board on which a patterned wire is provided, and a semiconductor element which is provided on the board.

The plurality of semiconductor devices are bonded to each other using a metallic wire.

The semiconductor module is desired to have a large current capacity.

However, if the number of metallic wires is increased in order to increase the current capacity, an area in which the metallic wires are bonded to each other becomes large and the size of the semiconductor module is increased.

If the metallic wire becomes thicker, reliability for bonding by using a wire-bonding method may be lowered.

For this reason, development of a semiconductor device and a semiconductor module which can obtain reduction in size and improvement of reliability is desired.

### BRIEF DESCRIPTION OF THE DRAWINGS

FIG. 1 is a schematic perspective view illustrating the semiconductor device 1 according to the first embodiment;

FIG. 2 is a schematic perspective view illustrating a base body 3;

FIG. 3 is a schematic diagram illustrating the semiconductor module 100 according to the second embodiment;

FIG. 4 is a cross-sectional view taken along line A-A in FIG. 3;

FIGS. 5A to 5E are schematic processing diagrams illustrating the manufacturing method of the semiconductor device 1 and the manufacturing method of the semiconductor module 100;

FIGS. 6A and 6B are schematic perspective diagrams illustrating the semiconductor device 1a;

FIGS. 7A and 7B are schematic perspective diagrams illustrating the semiconductor device 1b;

FIG. 8 is a schematic diagram illustrating the semiconductor device 1c; and

FIG. 9 is a schematic diagram illustrating the semiconductor module 100a.

### DETAILED DESCRIPTION

In general, according to one embodiment, a semiconductor device includes a first base portion, a second base portion, a third base portion, and a semiconductor element. The first base portion is extended in a first direction. The second base portion is provided parallel with the first base portion in a second direction intersecting with the first direction and is extended in the first direction. The third base portion is provided parallel between the first base portion and the second base portion in the second direction and is extended in the first direction. The semiconductor element is provided on at least one of the first base portion, the second base portion, and the third base portion. A first end portion of the first base portion in the first direction is positioned closer to a side on which the semiconductor element is provided than a second end portion on a side opposite to the first end portion of the first base portion, in a third direction intersecting with the first direction and the second direction. A third end portion on the first end portion side of the second base portion is positioned closer to the side on which the semiconductor element is provided than a fourth end portion on the second end portion side of the second base portion in the third direction. A fifth end portion on the first end portion side of the third base portion is positioned closer to the side on which the semiconductor element is provided than a sixth end portion on the second end portion side of the third base portion in the third direction.

Hereinafter, embodiments will be described with reference to the drawings. In the drawings, the same components are denoted by the same reference numerals and descriptions thereof will be appropriately omitted.

In the drawings, arrows X, Y, and Z represent three directions which are orthogonal to each other. For example, a direction vertical to a major surface of a board 11 is set as a Z-direction (corresponding to an example of a third direction). One direction in a plane which is parallel with the major surface of the board 11 is set as a Y-direction (corresponding to an example of a second direction). A direction vertical to the Z-direction and the Y-direction is set as an X-direction (corresponding to an example of a first direction).

### First Embodiment

A semiconductor device 1 according to a first embodiment will be described.

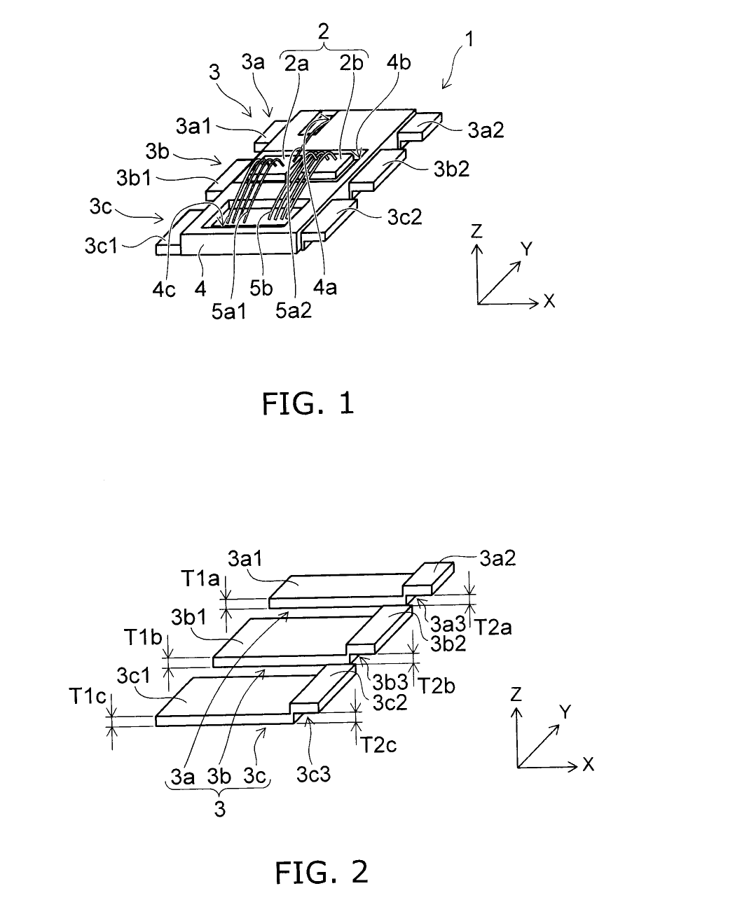

FIG. 1 is a schematic perspective view illustrating the semiconductor device 1 according to the first embodiment.

FIG. 2 is a schematic perspective view illustrating a base body 3.

As illustrated in FIG. 1, the semiconductor device 1 includes a semiconductor element 2, the base body 3, a case 4, and wires 5a1, 5a2, and 5b.

The semiconductor element 2 is provided on a base portion 3b (corresponding to an example of a third base portion).

The semiconductor element 2 may be provided on any one of a base portion 3a (corresponding to an example of a first base portion), the base portion 3b, and a base portion 3c (corresponding to an example of a second base portion).

A semiconductor element 2a may be a metal-oxide-semiconductor field-effect transistor (MOSFET).

When being a MOSFET, the semiconductor element 2a may have electrodes on a surface and a back surface.

In this case, a source electrode and a gate electrode may be provided on the surface which is a surface opposite to the base portion 3b side.

That is, the source electrode and the gate electrode of the MOSFET may be exposed from the case 4.

The source electrode is electrically connected to the base portion 3c through the wire 5a1.

The gate electrode is electrically connected to the base portion 3a through the wire 5a2.

A drain electrode may be provided on the back surface which is a surface on the base portion 3b side.

The drain electrode is electrically connected to the base portion 3b by using a bonding member such as soldering.

A semiconductor element 2b may be a diode or the like, for example.

When being a diode, the semiconductor element 2b may have electrodes on a surface and a back surface.

In this case, an anode electrode may be provided on the surface which is the surface opposite to the base portion 3b side.

That is, the anode electrode of the diode may be exposed from the case 4.

The anode electrode is electrically connected to the base portion 3c through the wire 5b.

A cathode electrode may be provided on the back surface which is the surface on the base portion 3b side.

The cathode electrode is electrically connected to the base portion 3b by using a bonding member such as soldering. A type or a bonding method of the semiconductor element 2 is not limited to the above description and may be appropriately changed.

As illustrated in FIG. 1 and FIG. 2, the base portion 3a, the base portion 3b, and the base portion 3c are provided on the base body 3.

The base portion 3a, the base portion 3b, and the base portion 3c are separated at a predetermined distance and arranged in the Y-direction. Each of the base portion 3a, the base portion 3b, and the base portion 3c is extended in the X-direction.

The base portion 3a, the base portion 3b, and the base portion 3c are integrally formed by the case 4.

An end portion 3a1 (corresponding to an example of a second end portion) of the base portion 3a, an end portion 3b1 (corresponding to an example of a sixth end portion) of the base portion 3b, and an end portion 3c1 (corresponding to an example of a fourth end portion) of the base portion 3c protrude from one end face of the case 4 in the X-direction.

An end portion 3a2 (corresponding to an example of a first end portion) of the base portion 3a, an end portion 3b2 (corresponding to an example of a fifth end portion) of the base portion 3b, and an end portion 3c2 (corresponding to an example of a third end portion) of the base portion 3c protrude from another end face of the case 4 in the X-direction.

The end portion 3a1 is in the same plane as that of an area of the base portion 3a to which the wire 5a is bonded, in the Z-direction.

The end portion 3b1 is in the same plane as that of an area of the base portion 3b at which the semiconductor elements 2a and 2b are provided, in the Z-direction.

The end portion 3c1 is in the same plane as that of an area of the base portion 3c to which the wire 5a1 and the wire 5b are bonded, in the Z-direction.

A gap 3a3 is provided under the end portion 3a2.

If a thickness dimension of the base portion 3a is set as T1a and a dimension of the gap 3a3 in the Z-direction is set as T2a, T1a≦T2a is satisfied.

In this case, the dimension T2a is favorable to be the same as or slightly longer than the thickness dimension T1a.

A gap 3b3 is provided under the end portion 3b2.

If a thickness dimension of the base portion 3b is set as T1b and a dimension of the gap 3b3 in the Z-direction is set as T2b, T1b≦T2b is satisfied.

In this case, the dimension T2b is favorable to be the same as or slightly longer than the thickness dimension T1b.

A gap 3c3 is provided under the end portion 3c2.

If a thickness dimension of the base portion 3c is set as T1c and a dimension of the gap 3c3 in the Z-direction is set as T2c, T1c≦T2c is satisfied.

In this case, the dimension T2c is favorable to be the same as or slightly longer than the thickness dimension T1c.

The end portion 3a2, the end portion 3b2, and the end portion 3c2 may be formed by plastic working (bending processing).

Materials of the base portion 3a, the base portion 3b, and the base portion 3c are not particularly limited as long as the material has conductivity.

In this case, if performing of plastic working, friction stir welding, or the like is considered, the materials of the base portion 3a, the base portion 3b, and the base portion 3c are favorable to be aluminium, copper, or the like, for example.

For example, nickel plating may be performed on surfaces of the base portion 3a, the base portion 3b, and the base portion 3c. A thickness dimension in nickel plating may be 10 μm, for example.

Thickness dimensions of the base portion 3a, the base portion 3b, and the base portion 3c are not particularly limited.

In this case, if performing of plastic working, friction stir welding, or the like is considered, the thickness dimensions of the base portion 3a, the base portion 3b, and the base portion 3c may be appropriately 1 mm, for example.

The case 4 covers a portion of each of the base portion 3a, the base portion 3b, and the base portion 3c which are arranged in the Y-direction.

A hole portion 4a (corresponding to an example of a first exposure portion), a hole portion 4b (corresponding to an example of a third exposure portion), and a hole portion 4c (corresponding to an example of a second exposure portion) are provided in the case 4.

The hole portion 4a is provided in the base portion 3a.

A face to which the wire 5a2 of the base portion 3a is bonded is exposed in the hole portion 4a.

The hole portion 4b is provided in the base portion 3b.

A face to which the semiconductor elements 2a and 2b of the base portion 3b are bonded is exposed in the hole portion 4b.

The hole portion 4c is provided in the base portion 3c.

A face to which the wires 5a1 and 5b of the base portion 3c are bonded is exposed in the hole portion 4c.

The base portion 3a is exposed on a face of the case 4 opposite to a face on which the hole portion 4a is opened.

The base portion 3b is exposed on a face of the case 4 opposite to a face on which the hole portion 4b is opened.

The base portion 3c is exposed on a surface of the case 4 opposite to a face on which the hole portion 4c is opened.

Faces of the base portions 3a to 3c which are exposed from the face opposite to the face on which the hole portions 4a to 4c are opened are set to be a disposition surface when the semiconductor device 1 is provided on the board 11, which will be described later.

A material of the case 4 is not particularly limited as long as the material has insulation properties.

In this case, if processability when the base portion 3a, the base portion 3b, and the base portion 3c are integrally formed is considered, the material of the case 4 is favorable to be a resin material, for example.

An example of the resin material may include epoxy resin and like, for example.

A silica filler and the like may be added to the resin material.

The wires 5a1, 5a2, and 5b may be an aluminum wire or the like which has a diameter dimension of appropriately 500 μm.

The wires 5a1, 5a2, and 5b may be bonded by using a wire bonding method, for example.

Dimensions, materials, the number of wires, a bonding method, and the like of the wires 5a1, 5a2, and 5b are not limited to the above descriptions and may be appropriately changed.

In the semiconductor device 1 according to the embodiment, an end portion 3a1 of an adjacent semiconductor device 1 is provided in the gap 3a3 under the end portion 3a2. An end portion 3b1 of an adjacent semiconductor device 1 is provided in the gap 3b3 under the end portion 3b2. An end portion 3c1 of an adjacent semiconductor device 1 is provided in the gap 3c3 under the end portion 3c2.

Thus, the end portion 3a1 and the end portion 3a2, the end portion 3b1 and the end portion 3b2, and the end portion 3c1 and the end portion 3c2 may be respectively directly bonded to each other.

For this reason, it is possible to increase current capacity, compared to when bonding is performed through the wire and the like. It is possible to obtain reduction in size and improvement of reliability.

### Second Embodiment

Next, a semiconductor module 100 according to a second embodiment will be described.

In the following descriptions, a case where the semiconductor module 100 includes a plurality of the same type semiconductor devices 1 will be described as an example.

For example, the descriptions may be similarly applied to, for example, a case when the semiconductor module 100 includes a plurality of semiconductor devices which have different type semiconductor elements.

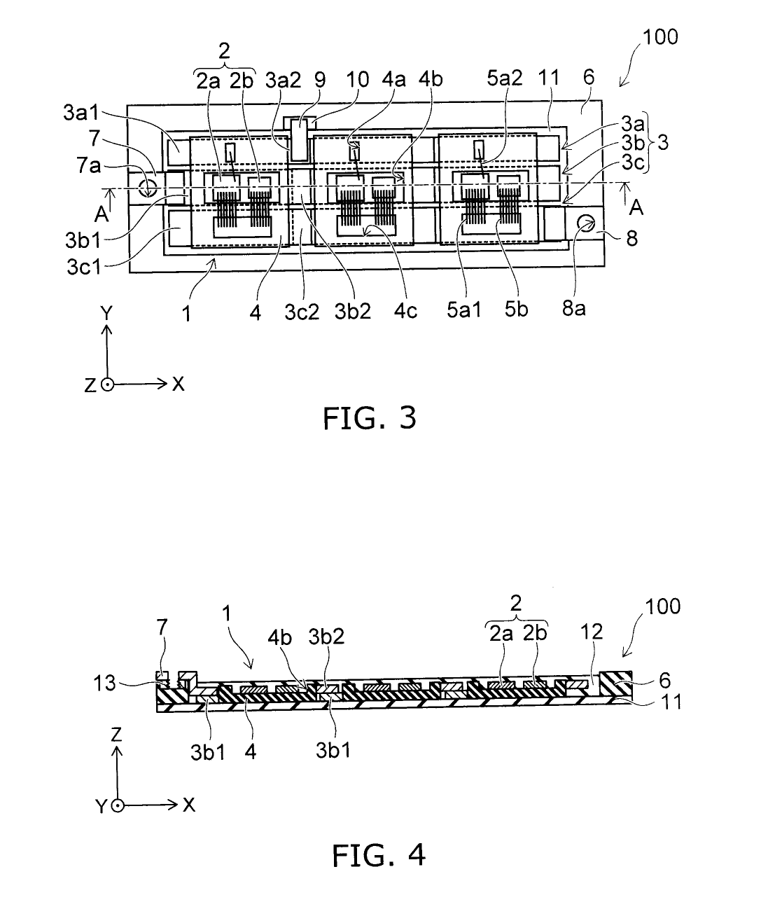

FIG. 3 is a schematic diagram illustrating the semiconductor module 100 according to the second embodiment.

In FIG. 3, a sealing portion 12 is omitted in order to avoid complexity.

FIG. 4 is a cross-sectional view taken along line A-A in FIG. 3.

As illustrated in FIG. 3 and FIG. 4, the semiconductor module 100 includes the semiconductor device 1, a frame portion 6, a terminal 7, a terminal 8, a connector 9, a terminal 10, the board 11, the sealing portion 12, and a fastening portion 13.

As illustrated in FIG. 3 and FIG. 4, the plurality of semiconductor devices 1 are provided on the board 11.

The plurality of semiconductor devices 1 are bonded onto the board 11, for example.

The plurality of semiconductor devices 1 are arranged in the X-direction.

An end portion 3a2 of a base portion 3a of an adjacent semiconductor device 1 is provided on the end portion 3a1 of the base portion 3a.

An end portion 3b2 of a base portion 3b of an adjacent semiconductor device 1 is provided on the end portion 3b1 of the base portion 3b.

An end portion 3c2 of a base portion 3c of an adjacent semiconductor device 1 is provided on the end portion 3c1 of the base portion 3c.

The end portion 3a1 and the end portion 3a2, the end portion 3b1 and the end portion 3b2, and the end portion 3c1 and the end portion 3c2 are respectively bonded.

That is, the plurality of semiconductor devices 1 are connected to each other in the X-direction.

A bonding method is not particularly limited and, for example, a friction stir welding method, an ultrasonic bonding method, or the like is favorable.

The number of the semiconductor devices 1 is not limited to the description and two semiconductor devices 1 or more may be provided.

The frame portion 6 is provided on the board 11.

The frame portion 6 is bonded onto the board 11, for example.

The frame portion 6 surrounds the plurality of semiconductor devices 1.

A material of the frame portion 6 is not particularly limited as long as the material has insulation properties.

In this case, if processability is considered, the material of the frame portion 6 is favorable to be a resin material, for example.

An example of the resin material may include epoxy resin and like, for example.

One end portion of the terminal 7 is provided on the frame portion 6.

A hole portion 7a is provided in the one end portion side of the terminal 7.

The hole portion 7a is provided just on the fastening portion 13 which is buried in the frame portion 6. For this reason, the terminal 7 is attached along with a solderless terminal (not illustrated) when the solderless terminal (not illustrated) and the like are fastened to the fastening portion 13. The one end portion of the terminal 7 may be bonded onto the frame portion 6.

Another end portion of the terminal 7 is bonded onto the end portion 3b1 of the base portion 3b.

A bonding method is not particularly limited and, for example, a friction stir welding method, an ultrasonic bonding method, or the like is favorable.

The terminal 7 may be formed by plastic working.

One end portion of the terminal 8 is provided on the frame portion 6.

A hole portion 8a is provided in the one end portion of the terminal 8.

The hole portion 8a is provided just on the fastening portion 13 which is buried in the frame portion 6. For this reason, the terminal 8 is attached along with a solderless terminal (not illustrated) when the solderless terminal (not illustrated) and the like are fastened to the fastening portion 13. The one end portion of the terminal 8 may be bonded onto the frame portion 6.

Another end portion of the terminal 8 is bonded onto the end portion 3c2 of the base portion 3c.

A bonding method is not particularly limited and, for example, a friction stir welding method, an ultrasonic bonding method, or the like is favorable.

The terminal 8 may be formed by plastic working.

Materials of the terminal 7 and the terminal 8 are not particularly limited as long as the material has conductivity.

In this case, if performing of plastic working, friction stir welding, or the like is considered, the materials of the terminal 7 and the terminal 8 are favorable to be aluminium, copper, or the like, for example.

Thickness dimensions of the terminal 7 and the terminal 8 are not particularly limited.

In this case, if performing of plastic working, friction stir welding, or the like is considered, the thickness dimensions of the terminal 7 and the terminal 8 may be appropriately 1 mm.

The connector 9 is electrically connected to the end portion 3a2 of the base portion 3a and the terminal 10.

One end portion of the connector 9 is bonded onto the end portion 3a2 of the base portion 3a.

Another end portion of the connector 9 is bonded onto the terminal 10.

Bonding of the connector 9 and the end portion 3a2 and bonding of the connector 9 and the terminal 10 are not particularly limited, for example, a friction stir welding method, an ultrasonic bonding method, or the like is favorable.

The terminal 10 is buried in the frame portion 6.

The terminal 10 may be buried in the frame portion 6 by using an insert molding method and the like.

A material of the terminal 10 is not particularly limited as long as the material has conductivity.

The material of the terminal 10 may be aluminium, copper, or the like, for example.

The board 11 has a plate shape.

A thickness dimension of the board 11 may be appropriately 2 mm.

A material of the board 11 is not particularly limited as long as the material has insulation properties.

In this case, if dissipation of heat generated in the semiconductor device 1 is considered, the material of the board 11 is favorable to be, for example, ceramics such as aluminum oxide and aluminum nitride.

The sealing portion 12 is provided in the frame portion 6 and covers the plurality of the semiconductor devices 1.

If the sealing portion 12 is provided, the semiconductor elements 2a and 2b, and the wires 5a1, 5a2, and 5b may be covered. Thus, it is possible to suppress moistures, contaminants, and the like from being brought into contact with the semiconductor elements 2a and 2b or the wires 5a1, 5a2, and 5b. It is possible to suppress applying of mechanical external force to the semiconductor elements 2a and 2b or the wires 5a1, 5a2, and 5b. For this reason, it is possible to improve reliability of the semiconductor module 100.

A material of the sealing portion 12 is not particularly limited as long as the material has insulation properties.

In this case, if mitigation of thermal stress due to heat generated in the semiconductor device 1 is considered, the material of the sealing portion 12 is favorable to be soft resin.

An example of the soft resin may include a silicone resin and the like, for example.

The fastening portion 13 is buried in the frame portion 6.

The fastening portion 13 may be buried in the frame portion 6 by using an insert molding method, and the like.

For example, a female screw is processed on the fastening portion 13. The fastening portion 13 may be a nut or the like, for example.

In the semiconductor module 100 according to the embodiment, the end portion 3a2 and the end portion 3a1 of the adjacent semiconductor device 1, the end portion 3b2 and the end portion 3b1 of the adjacent semiconductor device 1, and the end portion 3c2 and the end portion 3c1 of the adjacent semiconductor device 1 are respectively overlapped.

Thus, the end portion 3a1 and the end portion 3a2, the end portion 3b1 and the end portion 3b2, and the end portion 3c1 and the end portion 3c2 are respectively directly bonded.

For this reason, it is possible to increase current capacity, compared to when bonding is performed through the wire and the like. It is possible to obtain reduction in size and improvement of reliability.

### Third Embodiment

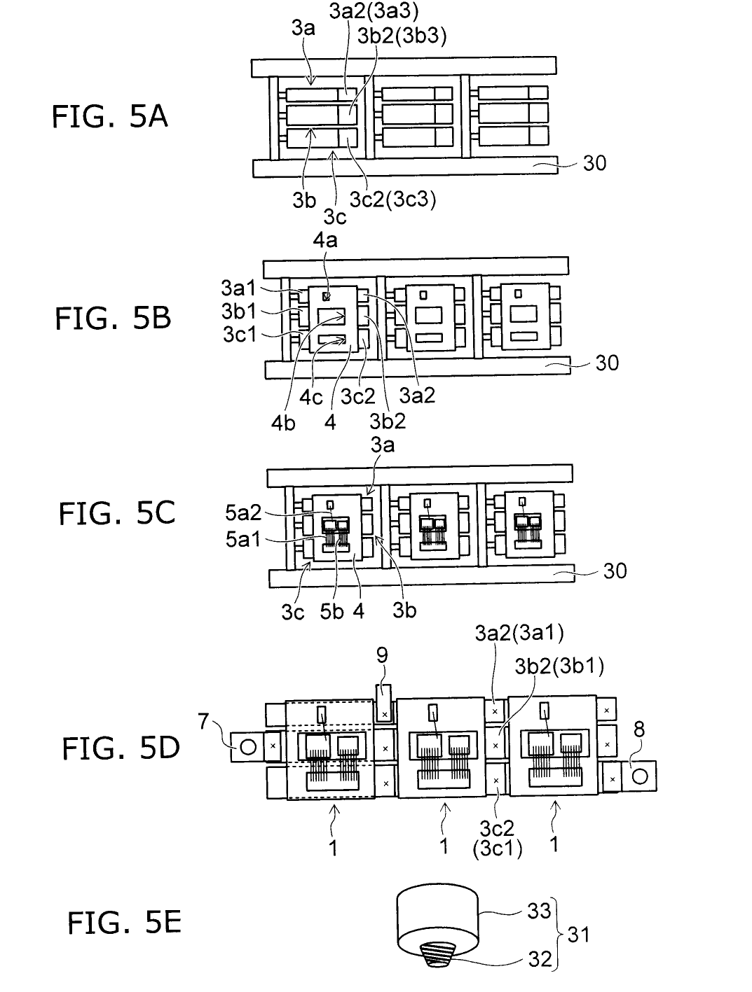

Next, a manufacturing method of a semiconductor device 1 according to a third embodiment and a manufacturing method of a semiconductor module 100 will be described. FIGS. 5A to 5D are schematic processing diagrams illustrating the manufacturing method of the semiconductor device 1 and the manufacturing method of the semiconductor module 100.

FIG. 5E is a schematic perspective view illustrating a tool 31 used in the friction stir welding method.

First, as illustrated in FIG. 5A, a base portion 3a, a base portion 3b, and a base portion 3c which are respectively linked to a frame member 30 are formed.

At this time, an end portion 3a2 is bent to provide a gap 3a3 under the end portion 3a2.

An end portion 3b2 is bent to provide a gap 3b3 under the end portion 3b2.

An end portion 3c2 is bent to provide a gap 3c3 under the end portion 3c2.

The base portion 3a, the base portion 3b, the base portion 3c, the end portion 3a2, the end portion 3b2, and the end portion 3c2 may be processed by using a mold.

Then, as illustrated in FIG. 5B, a case 4 is formed so as to cover a portion of each of the base portion 3a, the base portion 3b, and the base portion 3c.

Formation of the case 4 causes the base portion 3a, the base portion 3b, and the base portion 3c to be integrally formed.

The case 4 may be formed from epoxy resin and the like to which, for example, a silica filler or the like is added.

A hole portion 4a, a hole portion 4b, and a hole portion 4c are provided in the case 4 and a portion of each of the base portion 3a, the base portion 3b, and the base portion 3c is exposed in the case 4.

An end portion 3a1, an end portion 3b1, an end portion 3c1, the end portion 3a2, the end portion 3b2, and the end portion 3c2 protrude from the case 4.

Then, as illustrated in FIG. 5C, a semiconductor element 2 is mounted on a base body 3 by using a die-bonding method and electrodes of the semiconductor element 2 and the base body 3 are electrically connected to each other with a wire by using a wire bonding method.

For example, semiconductor elements 2a and 2b are mounted on the base portion 3b which is exposed in the hole portion 4b. At this time, a drain electrode of the semiconductor element 2a is electrically connected to the base portion 3b through a bonding member such as soldering.

A cathode electrode of the semiconductor element 2b is connected to the base portion 3b through a bonding member such as soldering.

Then, a source electrode of the semiconductor element 2a and the base portion 3a which is exposed in the hole portion 4a are electrically connected to each other by using a wire 5a2.

A gate electrode of the semiconductor element 2a and the base portion 3c which is exposed in the hole portion 4c are electrically connected to each other by using a wire 5a1.

An anode electrode of the semiconductor element 2b and the base portion 3c which is exposed in the hole portion 4c are electrically connected to each other by using the wire 5b.

As described above, a plurality of semiconductor devices 1 may be integrally manufactured.

Then, the semiconductor device 1 is cut off from the frame member 30.

For example, the semiconductor device 1 is cut off from the frame member 30 by using a mold.

In this manner, the semiconductor device 1 illustrated in FIG. 1 may be manufactured.

Then, as illustrated in FIG. 5D, the plurality of semiconductor devices 1 are linked.

An end portion 3a2 of a base portion 3a of an adjacent semiconductor device 1 is placed on the end portion 3a1 of the base portion 3a.

An end portion 3b2 of a base portion 3b of the adjacent semiconductor device 1 is placed on the end portion 3b1 of the base portion 3b.

An end portion 3c2 of a base portion 3c of the adjacent semiconductor device 1 is placed on the end portion 3c1 of the base portion 3c.

An end portion of a terminal 7 is placed on the end portion 3b1 of the base portion 3b.

An end portion of a terminal 8 is placed on the end portion 3c2 of the base portion 3c.

An end portion of a connector 9 is placed on the end portion 3a2 of the base portion 3a.

The end portion 3a1 and the end portion 3a2, the end portion 3b1 and the end portion 3b2, the end portion 3c1 and the end portion 3c2, the end portion 3b1 and the terminal 7, the end portion 3c2 and the terminal 8, and the end portion 3a2 and the connector 9 are respectively bonded using a friction stir welding method.

In FIG. 5D, bonding locations represent “X”.

In a friction stir welding method, the tool 31 as illustrated in FIG. 5E may be used.

The tool 31 may include a probe 32 which has a groove on a side surface, and a shoulder 33 which is connected to the probe 32.

The probe 32 may have a diameter dimension of appropriately 1.5 mm and a height dimension of appropriately 1.2 mm, for example.

A diameter dimension of the shoulder 33 may be appropriately 4 mm, for example.

The tool 31 is rotated at the number of rotation which is appropriately 2000 rpm and the rotating tool 31 is pressed on an overlapped portion.

If the rotating tool 31 is pressed, friction heat causes a material of the overlapped portion to be softened.

The probe 32 is inserted into the softened material and is scanned in a horizontal direction at a speed of 500 mm per minute, for example.

If scanning is performed, the softened material is stirred and mixed and the overlapped portion is bonded.

Bonding may be performed by using an ultrasonic bonding method and the like.

Then, a frame portion 6 is bonded onto a board 11.

Then, the plurality of semiconductor devices 1 which are linked to each other is bonded onto a portion of the board 11 which is exposed in the frame portion 6.

An adhesive may be a silicone adhesive having thermal conductivity of appropriately 6 W/m·k.

Then, the connector 9 is bonded onto a terminal 10 which is buried in the frame portion 6.

Bonding may be performed by using a friction stir welding method, an ultrasonic bonding method, and the like, for example.

Then, the inside of the frame portion 6 is filled with silicone resin and the like to form a sealing portion 12.

In this manner, the semiconductor module 100 may be manufactured.

The manufacturing method of the semiconductor device 1 according to the embodiment and the manufacturing method of the semiconductor module 100 are described, but are not limited to specific numerical values, materials, and the like.

Semiconductor devices 1a to is and a semiconductor module 100a which will be described later may be manufactured by similar procedures.

### Fourth Embodiment

Then, a semiconductor device 1a according to a fourth embodiment will be described.

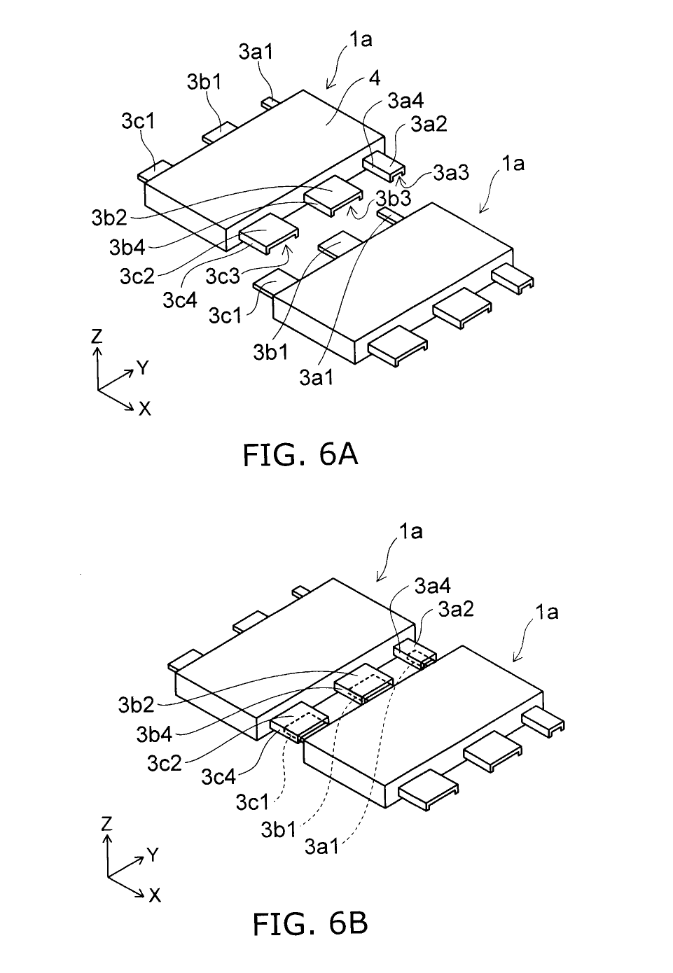

FIGS. 6A and 6B are schematic perspective diagrams illustrating the semiconductor device 1a.

FIG. 6A is a schematic perspective diagram illustrating the semiconductor device 1a before linkage.

FIG. 6B is a schematic perspective diagram illustrating the semiconductor device 1a after the linkage.

The semiconductor elements 2a and 2b, the wires 5a1, 5a2, and 5b, and the hole portions 4a, 4b, and 4c, and the like will be omitted in order to avoid complexity.

As illustrated in FIGS. 6A and 6B, in the semiconductor device 1a, a protrusion 3a4 (corresponding to an example of a first protrusion), a protrusion 3b4 (corresponding to an example of a third protrusion), and a protrusion 3c4 (corresponding to an example of a second protrusion) are provided.

Two protrusions 3a4 are respectively provided on end faces of both sides of the end portion 3a2 in the Y-direction. The two protrusions 3a4 are extended on the gap 3a3 side (end portion 3a1 side in the Z-direction). The end portion 3a1 of the adjacent semiconductor device 1a is inserted between the two protrusions 3a4.

Two protrusions 3b4 are respectively provided on end faces of both sides of the end portion 3b2 in the Y-direction. The two protrusions 3b4 are extended on the gap 3b3 side (end portion 3b1 side in the Z-direction). The end portion 3b1 of the adjacent semiconductor device 1a is inserted between the two protrusions 3b4.

Two protrusions 3c4 are respectively provided on end faces of both sides of the end portion 3c2 in the Y-direction. The two protrusions 3c4 are extended on the gap 3c3 side (end portion 3c1 side in the Z-direction). The end portion 3c1 of the adjacent semiconductor device 1a is inserted between the two protrusions 3c4.

The protrusions may be provided on the end portion 3a1, the end portion 3b1, and the end portion 3c1.

That is, a protrusion (corresponding to an example of a fourth protrusion) may be provided on the end portion 3a1 and protrude to the end portion 3a2 side in the Z-direction.

A protrusion (corresponding to an example of a fifth protrusion) may be provided on the end portion 3b1 and protrude to the end portion 3b2 side in the Z-direction.

A protrusion (corresponding to an example of a sixth protrusion) may be provided on the end portion 3c1 and protrude to the end portion 3c2 side in the Z-direction.

The end portions of the base portions of the adjacent semiconductor devices are overlapped at a portion at which bonding is performed by using a friction stir welding method, an ultrasonic bonding method, or the like.

In this case, force when bonding processing is performed is applied to the end portion.

For this reason, a position of the end portion may be shifted.

The portion at which bonding is performed may be supported by using a processing jig, but, a space for the processing jig supporting the portion is required and the dimensions of the semiconductor device in the Y-direction may be increased.

In the semiconductor device 1a according to the embodiment, since the protrusions 3a4, 3b4, 3c4 are provided, it is possible to suppress shift of the position of the portion at which bonding is performed.

For this reason, it is possible to obtain improvement of bonding quality and reduction in size of the semiconductor device 1a.

### Fifth Embodiment

A semiconductor device 1b according to a fifth embodiment will be described.

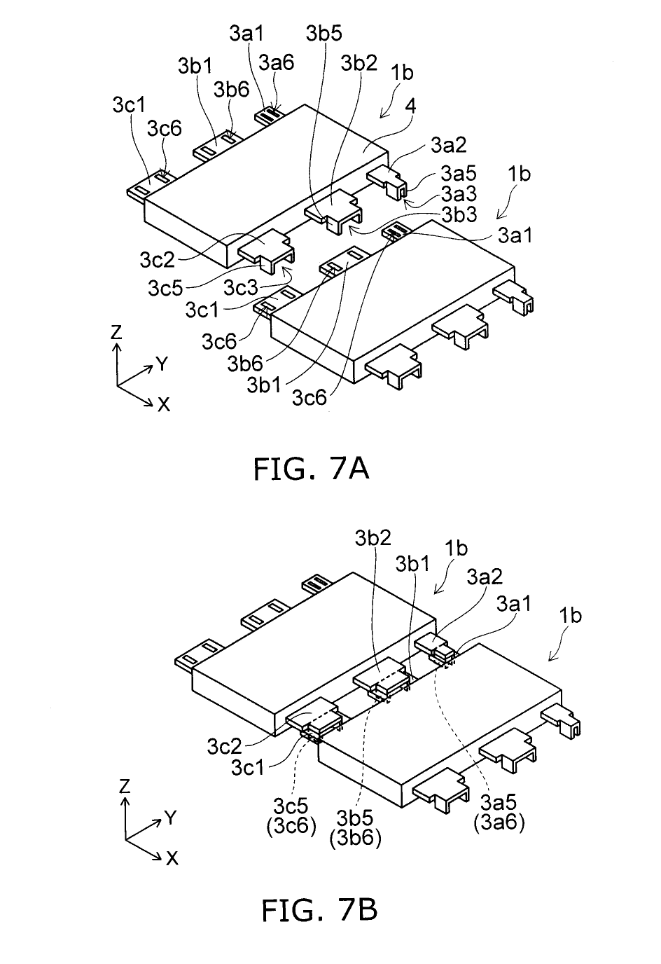

FIGS. 7A and 7B are schematic perspective diagrams illustrating the semiconductor device 1b.

FIG. 7A is a schematic perspective diagram illustrating the semiconductor device 1b before linkage.

FIG. 7B is a schematic perspective diagram illustrating the semiconductor device 1b after linkage.

The semiconductor elements 2a and 2b, the wires 5a1, 5a2, and 5b, and the hole portions 4a, 4b, and 4c, and the like will be omitted in order to avoid complexity.

As illustrated in FIGS. 7A and 7B, in the semiconductor device 1b, a protrusion 3a5 (corresponding to an example of a first protrusion), a protrusion 3b5 (corresponding to an example of a third protrusion), and a protrusion 3c5 (corresponding to an example of a second protrusion), a hole portion 3a6 (corresponding to an example of a first hole portion), a hole portion 3b6 (corresponding to an example of a third hole portion), and a hole portion 3c6 (corresponding to an example of a second hole portion) are provided.

The protrusion 3a5 is extended from the end portion 3a2 to the gap 3a3 side (end portion 3a1 side in the Z-direction).

The protrusion 3b5 is extended from the end portion 3b2 to the gap 3b3 side (end portion 3b1 side in the Z-direction).

The protrusion 3c5 is extended from the end portion 3c2 to the gap 3c3 side (end portion 3c1 side in the Z-direction).

The hole portion 3a6 for inserting the protrusion 3a5 is provided in the end portion 3a1.

The hole portion 3b6 for inserting the protrusion 3b5 is provided in the end portion 3b1.

The hole portion 3c6 for inserting the protrusion 3c5 is provided in the end portion 3c1.

A case where each of the protrusions 3a5, 3b5, 3c5, and the hole portions 3a6, 3b6, and 3c6 is provided by two is described.

However, each of the protrusions 3a5, 3b5, and 3c5, and the hole portions 3a6, 3b6, and 3c6 may be provided by at least one.

A taper for easy insertion may be provided on the protrusions 3a5, 3b5, and 3c5.

The protrusions may be provided on the end portion 3a1, the end portion 3b1, and the end portion 3c1 and the hole portions may be provided on the end portions 3a2, 3b2, and 3c2.

That is, the protrusion (corresponding to an example of a fourth protrusion) may be provided on the end portion 3a1 and protrude to the end portion 3a2 side in the Z-direction.

The protrusion (corresponding to an example of a fifth protrusion) may be provided on the end portion 3b1 and protrude to the end portion 3b2 side in the Z-direction.

The protrusion (corresponding to an example of a sixth protrusion) may be provided on the end portion 3c1 and protrude to the end portion 3c2 side in the Z-direction.

A hole portion (corresponding to an example of a fourth hole portion) which is provided on the end portion 3a2, a hole portion (corresponding to an example of a sixth hole portion) which is provided on the end portion 3b2, and a hole portion (corresponding to an example of a fifth hole portion) which is provided on the end portion 3c2 may be provided.

In the semiconductor device 1b according to the embodiment, since the protrusions 3a5, 3b5, and 3c5, and the hole portions 3a6, 3b6, 3c6 are provided, it is possible to suppress shift of the position of the portion at which bonding is performed.

For this reason, it is possible to obtain improvement of bonding quality and reduction in size of the semiconductor device 1b.

### Sixth Embodiment

Next, a semiconductor device 1c and a semiconductor module 100a according to a sixth embodiment will be described.

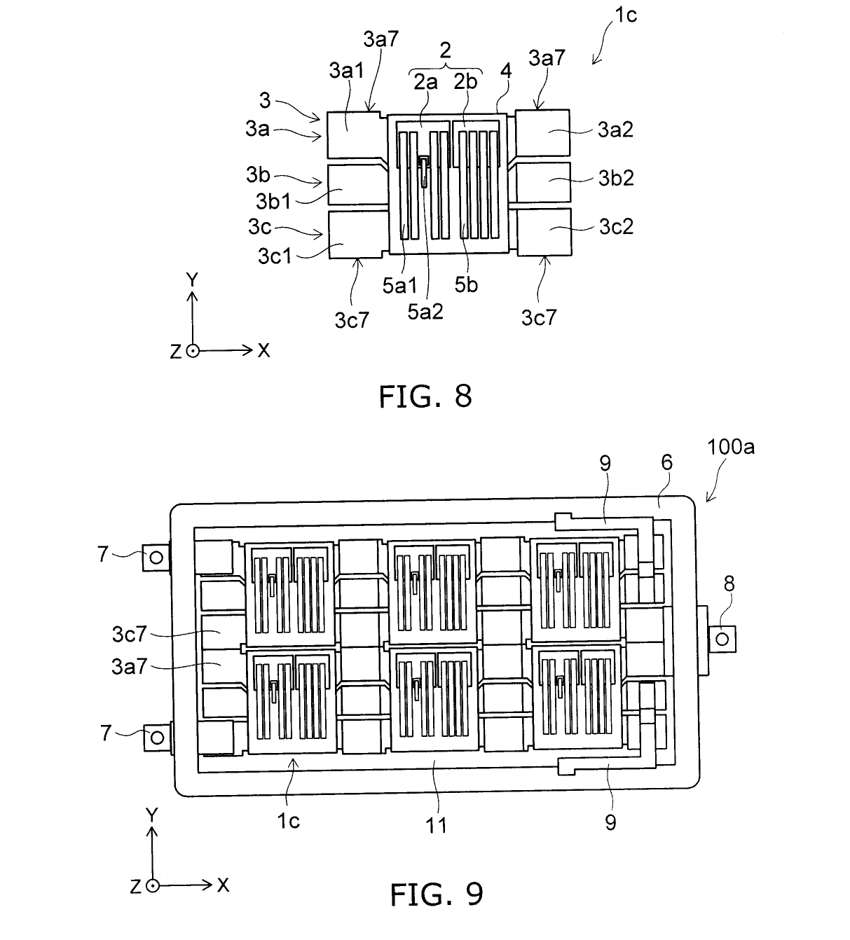

FIG. 8 is a schematic diagram illustrating the semiconductor device 1c.

FIG. 9 is a schematic diagram illustrating the semiconductor module 100a.

The hole portions 4a, 4b, and 4c, the sealing portion 12, and the like will be omitted in order to avoid complexity.

As illustrated in FIG. 8, the semiconductor device 1c includes a semiconductor element 2, a base body 3, a case 4, and wires 5a1, 5a2, and 5b.

A drain electrode of a semiconductor element 2a is electrically connected to a base portion 3a in the semiconductor device 1c.

A source electrode is electrically connected to a base portion 3c through the wire 5a1.

A gate electrode is electrically connected to a base portion 3b through the wire 5a2.

A cathode electrode of a semiconductor element 2b is electrically connected to the base portion 3a.

An anode electrode is electrically connected to the base portion 3c through the wire 5b.

The semiconductor device 1c further includes a protrusion 3a7 (corresponding to an example of a seventh protrusion) and a protrusion 3c7 (corresponding to an example of an eighth protrusion).

The protrusion 3a7 protrudes from an end face of the end portion 3a1 and an end face of the end portion 3a2 in the Y-direction toward the outside of the semiconductor device 1c.

The protrusion 3c7 protrudes from an end face of the end portion 3c1 and an end face of the end portion 3c2 in the Y-direction toward the outside of the semiconductor device 1c.

As illustrated in FIG. 9, in the semiconductor module 100a, three semiconductor devices 1c linked to each other in the X-direction are arranged to form two sets in the Y-direction.

Thus, the protrusion 3c7 and a protrusion 3a7 of an adjacent semiconductor device is come into contact with each other in the Y-direction.

That is, the semiconductor module 100a has a 2-in-1 configuration in which a plurality of semiconductor devices 1c is connected in series to each other to have two stages.

The semiconductor device 1c according to the embodiment includes the protrusions 3a7 and 3c7, and thus it is easy that the semiconductor devices is are arranged in a matrix using series and parallel.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. A semiconductor device comprising:
a first base portion that is extended in a first direction;
a second base portion that is provided parallel with the first base portion in a second direction intersecting with the first direction and is extended in the first direction;
a third base portion that is provided parallel between the first base portion and the second base portion in the second direction and is extended in the first direction; and
a semiconductor element that is provided on at least one of the first base portion, the second base portion, and the third base portion,
wherein a first end portion of the first base portion in the first direction is positioned closer to a side on which the semiconductor element is provided than a second end portion on a side opposite to the first end portion of the first base portion, in a third direction intersecting with the first direction and the second direction,
a third end portion on the first end portion side of the second base portion is positioned closer to the side on which the semiconductor element is provided than a fourth end portion on the second end portion side of the second base portion in the third direction, and
a fifth end portion on the first end portion side of the third base portion is positioned closer to the side on which the semiconductor element is provided than a sixth end portion on the second end portion side of the third base portion in the third direction.

2. The device according to claim 1, wherein
when a thickness dimension of the first base portion is set to T1a, a dimension of a gap of the first end portion which is provided on a side opposite to the side on which the semiconductor element is provided is set to T2a, a thickness dimension of the second base portion is set to T1b, a dimension of a gap of the third end portion which is provided on a side opposite to the side on which the semiconductor element is provided is set to T2b, a thickness dimension of the third base portion is set to T1c, and a dimension of a gap of the fifth end portion which is provided on a side opposite to the side on which the semiconductor element is provided is set to T2c, the following expression is satisfied.
T1a≦T2a
T1b≦T2b
T1c≦T2c

3. The device according to claim 1, further comprising:
a first protrusion that is provided on the first end portion of the first base portion and protrudes to the second end portion side in the third direction;
a second protrusion that is provided on the third end portion of the second base portion and protrudes to the fourth end portion side in the third direction; and
a third protrusion that is provided on the fifth end portion of the third base portion and protrudes to the sixth end portion side in the third direction.

4. The device according to claim 3, further comprising:
a first hole portion that is provided in the second end portion of the first base portion;
a second hole portion that is provided in the fourth end portion of the second base portion; and
a third hole portion that is provided in the sixth end portion of the third base portion.

5. The device according to claim 1, further comprising:
a fourth protrusion that is provided on the second end portion of the first base portion and protrudes to the first end portion side in the third direction;
a fifth protrusion that is provided on the fourth end portion of the second base portion and protrudes to the third end portion side in the third direction; and
a sixth protrusion that is provided on the sixth end portion of the third base portion and protrudes to the fifth end portion side in the third direction.

6. The device according to claim 5, further comprising:
a fourth hole portion that is provided in the first end portion of the first base portion;
a fifth hole portion that is provided in the third end portion of the second base portion; and
a sixth hole portion that is provided in the fifth end portion of the third base portion.

7. The device according to claim 1, further comprising:
a seventh protrusion that is provided on the first base portion and protrudes to a side opposite to the third base portion side of the first base portion; and
an eighth protrusion that is provided on the second base portion and protrudes to a side opposite to the third base portion side of the second base portion.

8. The device according to claim 1, further comprising:
a case that covers portions of the first base portion, the second base portion, and the third base portion,
wherein the first end portion of the first base portion, the third end portion of the second base portion, and the fifth end portion of the third base portion protrude from one end face of the case in the first direction, and
the second end portion of the first base portion, the fourth end portion of the second base portion, and the sixth end portion of the third base portion protrude from another end face of the case in the first direction.

9. The device according to claim 8, wherein
the case includes a first exposure portion, a second exposure portion, and a third exposure portion,
the first base portion is exposed in the first exposure portion,
the second base portion is exposed in the second exposure portion, and
the third base portion is exposed in the third exposure portion.

10. The device according to claim 9, wherein
the first base portion is exposed on a surface opposite to a surface on which the first exposure portion of the case is opened,
the second base portion is exposed on a surface opposite to a surface on which the second exposure portion of the case is opened, and
the third base portion is exposed on a surface opposite to a surface on which the third exposure portion of the case is opened.

11. The device according to claim 1, wherein
a plurality of semiconductor elements is provided, and
the plurality of semiconductor elements correspond to at least one of a MOSFET and a diode.

12. The device according to claim 11, wherein
a source electrode and a gate electrode of the MOSFET are exposed from the case.

13. The device according to claim 11, wherein
an anode electrode of the diode is exposed from the case.

14. The device according to claim 8, wherein
the first base portion, the second base portion, and the third base portion have conductivity and contain at least one of aluminium and copper, and
the case has insulation properties.

15. A semiconductor module, comprising:
a plurality of the semiconductor devices according to claim 1,
wherein the plurality of semiconductor devices are linked to each other in the first direction,
the first end portion of the first base portion is bonded on the second end portion of the first base portion in the adjacent semiconductor device in the first direction,
the third end portion of the second base portion is bonded on the fourth end portion of the second base portion in the adjacent semiconductor device, and
the fifth end portion of the third base portion is bonded on the sixth end portion of the third base portion in the adjacent semiconductor device.

16. The module according to claim 15, wherein
a first protrusion which is provided on the first end portion of the first base portion comes into contact with an end face of the second end portion of the first base portion of the adjacent semiconductor device in the second direction intersecting with the first direction,
a second protrusion which is provided on the third end portion of the second base portion comes into contact with an end face of the fourth end portion of the second base portion of the adjacent semiconductor device in the second direction, and
a third protrusion which is provided on the fifth end portion of the third base portion comes into contact with an end face of the sixth end portion of the third base portion of the adjacent semiconductor device in the second direction.

17. The module according to claim 15, wherein
the first protrusion which is provided on the first end portion of the first base portion is provided in a first hole portion which is provided in the second end portion of the first base portion in the adjacent semiconductor device,
the second protrusion which is provided on the third end portion of the second base portion is provided in a second hole portion which is provided in the fourth end portion of the second base portion in the adjacent semiconductor device, and
the third protrusion which is provided on the fifth end portion of the third base portion is provided in a third hole portion which is provided in the sixth end portion of the third base portion in the adjacent semiconductor device.

18. The module according to claim 15, wherein
a fourth protrusion which is provided on the second end portion of the first base portion comes into contact with an end face of the first end portion of the first base portion of the adjacent semiconductor device in the second direction,
a fifth protrusion which is provided on the fourth end portion of the second base portion comes into contact with an end face of the third end portion of the second base portion of the adjacent semiconductor device in the second direction, and
a sixth protrusion which is provided on the sixth end portion of the third base portion comes into contact with an end face of the fifth end portion of the third base portion of the adjacent semiconductor device in the second direction.

19. The module according to claim 15, wherein
the fourth protrusion which is provided on the second end portion of the first base portion is provided in a fourth hole portion which is provided in the first end portion of the first base portion in the adjacent semiconductor device,
the fifth protrusion which is provided on the fourth end portion of the second base portion is provided in a fifth hole portion which is provided in the third end portion of the second base portion in the adjacent semiconductor device, and
the sixth protrusion which is provided on the sixth end portion of the third base portion is provided in a sixth hole portion which is provided in the fifth end portion of the third base portion in the adjacent semiconductor device.

20. The module according to claim 15, wherein
the plurality of semiconductor devices linked to each other in the first direction are arranged to form two sets in the second direction, and
a seventh protrusion which is provided on the first base portion and protrudes to a side opposite to the third base portion side of the first base portion and an eighth protrusion which is provided on the second base portion of the adjacent semiconductor device in the second direction and protrudes to a side opposite to the third base portion side of the second base portion come into contact with each other.
